(19) United States
(12) Patent Application Publication
(10) Pub. No.: US 2024/0096711 A1
(43) Pub. Date: Mar. 21, 2024

(54) METHOD FOR FORMING A SEMICONDUCTOR DEVICE STRUCTURE AND RELATED SEMICONDUCTOR DEVICE STRUCTURES

(71) Applicant: ASM IP Holding B.V., Almere (NL)

(72) Inventors: Qi Xie, Wilsele (BE); Chiyu Zhu, Helsinki (FI); Kiran Shrestha, Phoenix, AZ (US); Pauline Calka, Leuven (BE); Oreste Madia, Schaerbeek (BE); Jan Willem Maes, Wilrijk (BE); Michael Eugene Givens, Scottsdale, AZ (US)

(21) Appl. No.: 18/522,867

(22) Filed: Nov. 29, 2023

Related U.S. Application Data
(63) Continuation of application No. 16/834,657, filed on Mar. 30, 2020.
Application No. 16/834,657 is a division of application No. 15/707,786, filed on Sep. 18, 2017, now Pat. No. 10,607,895.

(51) Int. Cl. H01L 21/8238; H01L 27/092; H01L 29/49; H01L 29/51

(52) U.S. Cl. CPC H01L 21/823842; H01L 27/092; H01L 29/495; H01L 29/4966; H01L 29/513; H01L 29/517

(57) ABSTRACT

A method for forming a semiconductor device structure is disclosure. The method may include, depositing an NMOS gate dielectric and a PMOS gate dielectric over a semiconductor substrate, depositing a first work function metal over the NMOS gate dielectric and over the PMOS gate dielectric, removing the first work function metal over the PMOS gate dielectric, and depositing a second work function metal over the NMOS gate dielectric and over the PMOS gate dielectric. Semiconductor device structures including desired metal gate electrodes deposited by the methods of the disclosure are also disclosed.

### CROSS-REFERENCE TO RELATED APPLICATIONS

This application is a continuation of, and claims priority to, U.S. patent application Ser. No. 16/834,657 filed Mar. 30, 2020 titled METHOD FOR FORMING A SEMICONDUCTOR DEVICE STRUCTURE AND RELATED SEMICONDUCTOR DEVICE STRUCTURES; which is a divisional of U.S. patent application Ser. No. 15/707,786 filed Sep. 18, 2017 titled METHOD FOR FORMING A SEMICONDUCTOR DEVICE STRUCTURE AND RELATED SEMICONDUCTOR DEVICE STRUCTURES (now U.S. Pat. No. 10,607,895 issued Mar. 31, 2020); the disclosures of which are hereby incorporated by reference in their entirety.

### FIELD OF INVENTION

The present disclosure relates generally to methods for forming a semiconductor device structure and related semiconductor device structures; in particular, the disclosure relates to methods for forming gate electrodes for both NMOS and PMOS device structures.

### BACKGROUND OF THE DISCLOSURE

Complementary metal-oxide-semiconductor (CMOS) technology has conventionally utilized n-type and p-type polysilicon as the gate electrode material. However, doped polysilicon may not be an ideal gate electrode material for advanced technology node applications. For example, although doped polysilicon is conductive, there may still be a surface region which can be depleted of carriers under bias. This depleted region may appear as an extra gate insulator thickness, commonly referred to as gate depletion, and may contribute to the equivalent oxide thickness. While the gate depletion region may be thin, on the order of a few Angstroms, it may become significant as the gate oxide thicknesses are reduced in advance technology node applications. As a further example, polysilicon does not exhibit an ideal effective work function (eWF) for both NMOS and PMOS devices. To overcome the non-ideal effective work function of doped polysilicon, a threshold voltage adjustment implantation may be utilized. However, as device geometries reduce in advanced technology node applications, the threshold voltage adjustment implantation processes may become increasingly complex.

To overcome the problems associated with doped polysilicon gate electrodes, the non-ideal doped polysilicon gate material may be replaced with alternative materials, such as, for example, metals, metal nitrides and metal carbides. For example, the properties of a metal, a metal nitride, or a metal carbide may be utilized to provide a more ideal effective work function for both NMOS and PMOS device, wherein the effective work function of the gate electrode, i.e., the energy need to extract an electron, may be compatible with the barrier height of the semiconductor material. For example, in the case of PMOS devices, the effective work function is approximately 5.0-5.2 eV, and in the case of the NMOS devices, the effective work function is approximately 4.1-4.3 eV. Accordingly, methods are desired for forming gate electrode for both NMOS and PMOS devices with preferred effective work functions.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, methods for forming a semiconductor device structure are provided. The method may comprise depositing an NMOS gate dielectric and a PMOS gate dielectric over a semiconductor substrate, depositing a first work function metal over the NMOS gate dielectric and over the PMOS gate dielectric, removing the first work function metal over the PMOS gate dielectric, and depositing a second work function metal over the NMOS gate dielectric and over the PMOS gate dielectric.

In additional embodiments, a semiconductor device structure may be provided. The semiconductor device structure may comprise: a PMOS gate electrode disposed over a PMOS gate dielectric, wherein the PMOS gate electrode comprises a metal nitride film disposed directly over the PMOS gate dielectric and a molybdenum film disposed directly over the metal nitride film.

In further embodiments, a semiconductor device structure may be provided. The semiconductor device structure may comprise, a NMOS gate electrode disposed over a NMOS gate dielectric, wherein the NMOS gate electrode comprises a metal nitride film disposed directly over the NMOS gate dielectric, a first work function metal disposed directly over the metal nitride film, an additional metal nitride film disposed over the first work function metal and a molybdenum film disposed over the additional metal nitride film.

In yet further embodiments, a complementary metal-oxide-semiconductor device structure may be provided. The CMOS device structure may comprise: a PMOS gate electrode disposed over a PMOS gate dielectric, wherein the PMOS gate electrode comprises a first titanium nitride film disposed directly over the PMOS gate dielectric and a molybdenum film disposed directly over the first titanium nitride film. The CMOS device structure may also comprise: a NMOS gate electrode disposed over a NMOS gate dielectric, wherein the NMOS gate electrode comprises a second titanium nitride film disposed directly over the NMOS gate dielectric, a first work function metal disposed directly over the second titanium nitride film, a third titanium nitride film disposed over the first work function metal and a molybdenum film disposed over the third titanium nitride film.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIGS. 1-11 are simplified cross sectional views of semiconductor device structures including gate electrodes formed according to the embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein, the term “cyclic deposition” may refer to the sequential introduction of precursors (reactants) into a reaction chamber to deposit a film over a substrate and includes deposition techniques such as atomic layer deposition and cyclical chemical vapor deposition.

As used herein, the term “cyclical chemical vapor deposition” may refer to any process wherein a substrate is sequentially exposed to two or more volatile precursors, which react and/or decompose on a substrate to produce a desired deposition.

As used herein, the term “substrate” may refer to any underlying material or materials that may be used, or upon which, a device, a circuit or a film may be formed.

As used herein, the term “atomic layer deposition” (ALD) may refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

As used herein, the term “work function metal” may refer to any conductive metal-containing material that results in an appropriate effective work function when formed in, on or over the gate dielectric of a semiconductor device.

The present disclosure includes methods and semiconductor device structures that may be used to form gate electrodes comprising one or more work function metals, wherein the work function metals may be formed utilizing cyclical deposition processes, such as, for example, atomic layer deposition processes. The existing work function metals that may be utilized in the ALD formation of gate electrodes may have limitations due to their unsuitable effective work function values. For example, it is known that the effective work function of a material may vary as a function of its thickness. Therefore, as device geometries decrease in advance technology node applications, the thickness of the corresponding device films, such as the work function metal(s) of the gate electrode, may also decrease in thickness with an associated change in the value of effective work function. Such a change in the effective work function of the gate electrode may result in a non-ideal effective work function for both NMOS and PMOS device structures. Methods and structures are therefore required to provide a more desirable gate electrode. Examples of such methods and structures are disclosed in further detail herein.

The following non-limiting example embodiments of the disclosure may be illustrated using a non-limiting example CMOS process flow, commonly referred to in the art as “gate last”, wherein the gate electrode may be formed after source/drain region formation and associated high temperature activation processes. It should however be understood, that the “gate last” embodiments illustrated herein are non-limiting example embodiments of the processes that may be utilized in the formation of example CMOS device structures, including NMOS and PMOS device structures. The methods and semiconductor device structures of the embodiments of the disclosure described herein may also include a CMOS process flow commonly referred to in the art as “gate first”, wherein the gate electrode may be formed prior to source/drain formation and associated high temperature activation processes. Common CMOS process flows are described in U.S. Pat. No. 9,136,180, issued to Machkaoutsan et al., and incorporated by reference herein.

It should be noted that the various embodiments of methods and semiconductor device structures described herein include various steps in the design and composition of the semiconductor device structures that are well known and so, in the interest of brevity, many conventional steps and structures have only been mentioned briefly herein or omitted entirely. In addition, a number of example materials are given throughout the embodiments of the current disclosure, it should be noted that the chemical formulas given for each of the example materials should not be construed as limiting and that the non-limiting example materials given should not be limited by a given example stoichiometry.

In some embodiments, the methods of the disclosure may comprise depositing an NMOS gate dielectric and a PMOS gate dielectric over a semiconductor substrate, depositing a first work function metal over the NMOS gate dielectric and over the PMOS gate dielectric, removing the first work function metal over the PMOS gate dielectric, and depositing a second work function metal over the NMOS gate dielectric and over the PMOS gate dielectric.

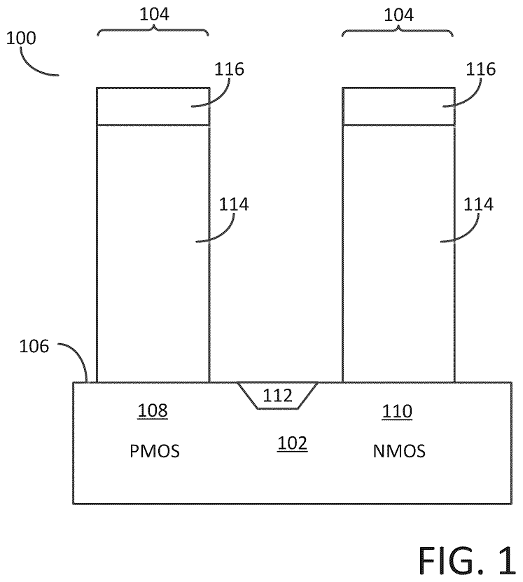

In more detail, and with reference to FIG. 1, a semiconductor device structure 100 may comprise a semiconductor substrate 102 and the sacrificial gate structures 104 formed over a surface 106 of the semiconductor substrate 102. The semiconductor substrate 102 may further comprise a PMOS region 108 and an NMOS region 110, wherein the PMOS and NMOS source/drain and channel regions may be subsequently formed. For the purpose of simplicity in describing the embodiments of the disclosure, only a single PMOS region 108 and a single NMOS region 110 are illustrate in FIG. 1; however, it should be appreciated that the methods and structures disclosed herein also apply to semiconductor device structures including a large number of PMOS regions and NMOS regions. The semiconductor substrate 102 may also comprise a shallow trench isolation (STI) 112, wherein the STI 112 separates and delineates the PMOS region 108 from the NMOS region 110.

The semiconductor substrate 102 may comprise, for example, a bulk silicon substrate or a silicon-on-insulator (SOI) substrate, wherein the SOI substrate further includes a support substrate and an intermediate buried oxide layer (not shown). In some embodiments, the semiconductor substrate 102 may comprise at least one of silicon, germanium, silicon germanium, silicon carbide, or a III-V material. In some embodiments, the semiconductor substrate 102 may be in the form of a fin structure for use in a FinFET type device, whereas in FIG. 1, semiconductor substrate 102 comprises a substantially planar surface 106.

As illustrated in FIG. 1, sacrificial gate structures 104 may be formed over the surface 106 of the semiconductor substrate 102. In some embodiments, the sacrificial gate structures 104 may comprise a sacrificial gate 114 and a sacrificial cap 116, wherein the sacrificial cap 116 may be formed directly over the sacrificial gate 114. The sacrificial gate structures 104 may be formed using conventional process steps, such as deposition, photolithography, and etching. The sacrificial gates 114 may comprise a polycrystalline silicon material and the sacrificial cap 116 may comprise a silicon oxide or a silicon nitride.

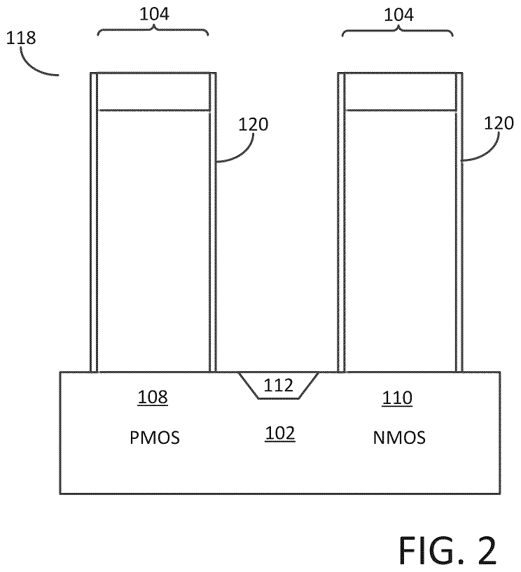

After sacrificial gate structure formation, spacers may be formed on either side of the sacrificial gate structures as illustrated in FIG. 2. In more detail, FIG. 2 illustrates semiconductor device structure 118 which comprises spacers 120. The spacers 120 may be formed adjacent to and on the sides of the sacrificial gate structures 104. In some embodiments of the disclosure, the spacers 120 may comprise a silicon nitride material and may be formed by an ALD process.

Upon spacer formation, processes for formation of source/drain regions in the semiconductor substrate 102 may be performed, including, but not limited to, etching, epitaxial deposition, stressing techniques, and ion implantation using the sacrificial gate structures as ion implantation masks. Processes for formation of source/drain regions in the semiconductor substrate 102 may result in the formation of PMOS region 108 and NMOS region 110 in semiconductor substrate 102 (details of source/drain and channel regions are not shown for simplicity).

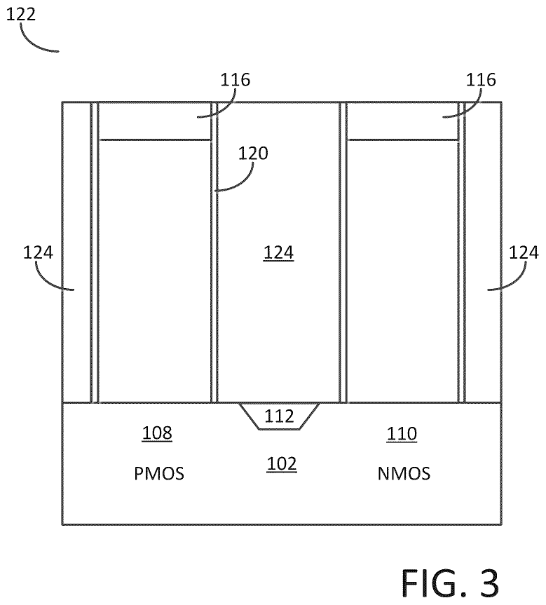

Embodiments of the disclosure may continue with the formation of an interlayer dielectric (ILD) comprising a dielectric material surrounding the spacers. FIG. 3 illustrates semiconductor device structure 122 comprising dielectric material 124. The dielectric material 124 may be formed utilizing deposition techniques, such as, chemical vapor deposition (CVD), low pressure chemical vapor deposition (LPCVD), or plasma enhanced chemical vapor deposition (PECVD). The dielectric material 124 may be deposited such that it fills the areas between the spacers 120 and covers the spacers 120 and the sacrificial caps 116. The dielectric material 124 may be subsequently planarized, for example, utilizing a chemical mechanical polishing process to provide a planar surface, the sacrificial caps 116 serving as a polish stop indicator.

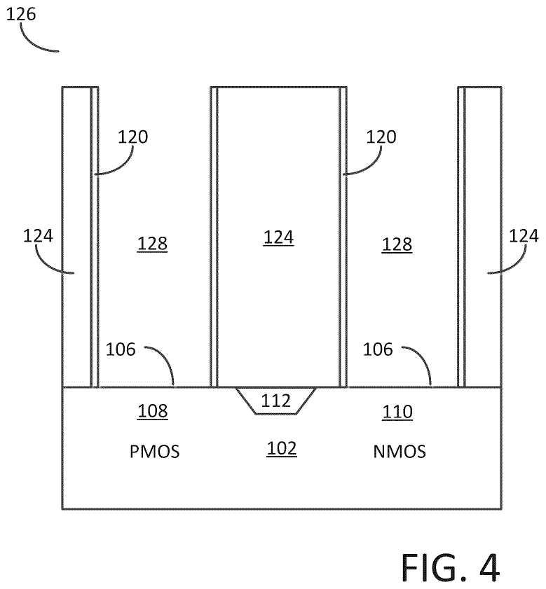

Upon deposition of the ILD, embodiments of the disclosure may continue by removing the sacrificial gate structures. For example, FIG. 4 illustrates semiconductor device structure 126 which shows the semiconductor device structure 122 of FIG. 3 after the removal of the sacrificial gate structures, whilst leaving the spacers 120 substantially intact. The removal of the sacrificial gate structures may expose surface 106 in the regions between the spacers 120. Removing the sacrificial gate structures comprises the formation of gate trenches 128, the gate trenches being bound by spacers 120 and surface 106. The sacrificial gate structures are removed by an etch process, the etch chemistry being selected such that the spacers 120 and the dielectric material 124 are not etched, or are not etched significantly. The sacrificial gate structure may be removed by a dry etch process, a wet etch process, or a combination thereof.

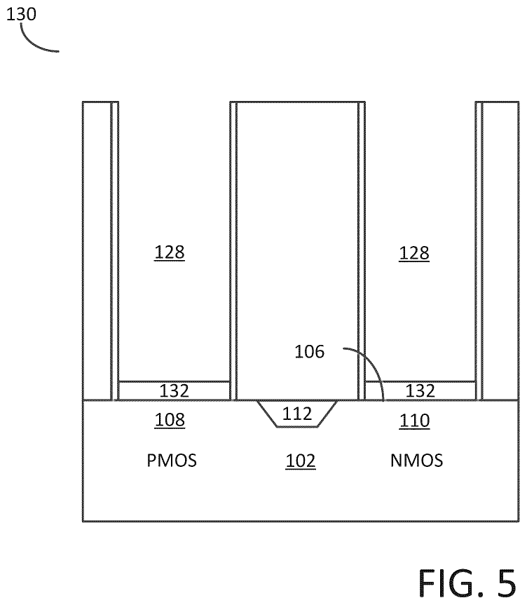

The embodiments of the disclosure may continue with the formation of an interface layer in the gate trenches. As illustrated in FIG. 5, a semiconductor device structure 130 may include an interface layer 132 that may be formed on the surface 106 of semiconductor substrate 102 disposed in the gate trenches 128. In some embodiments, the interface layer 132 may comprise a silicon oxide and may be selectively formed on the surface 106 utilizing a chemical oxidation process to oxidize the surface 106 of semiconductor substrate 102. In some embodiments, methods may comprise forming the interface layer 132 disposed over the channel region of the NMOS region and over the channel region of the PMOS region 108.

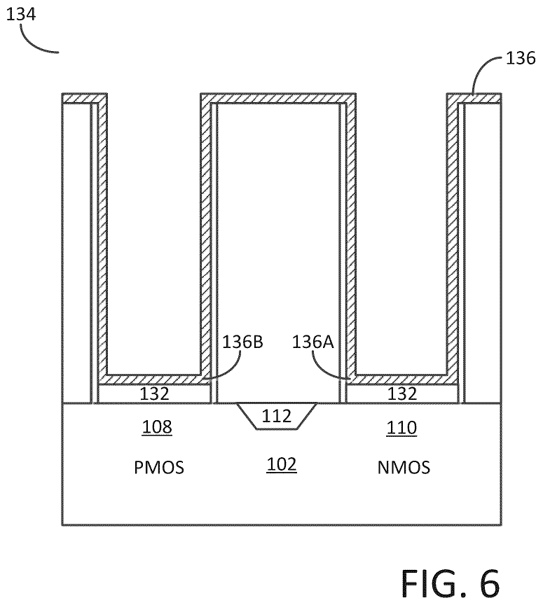

The embodiments of the disclosure may further comprise forming a gate dielectric. As a non-limiting example embodiment, a conformal layer of high-k dielectric material may be formed over the semiconductor device structure 130 of FIG. 5, resulting in the semiconductor device structure 134 as illustrate in FIG. 6. For example, the high-k dielectric material 136 disposed over the NMOS region 110 may be denoted as NMOS dielectric 136A and the high-k dielectric material 136 disposed over the PMOS region 108 may be denoted as PMOS dielectric 136B. Therefore in some embodiments of the disclosure, forming the NMOS gate dielectric 136A and the PMOS gate dielectric 136B may comprise depositing a high-k dielectric material 136 directly over the interface layer 132.

In some embodiments, the high-k dielectric material 136 may comprise at least one of hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃) or lanthanum oxide (La₂O₃) or mixtures/laminates thereof. In some embodiments, the high-k dielectric material 136 may comprise at least one of a dielectric metal oxide, such as a transition metal oxide or aluminum oxide, metal silicates, dielectric metal oxynitride or mixtures thereof. In some embodiments of the disclosure, the high-k dielectric material 136 may be conformally deposited using an atomic layer deposition process. In some embodiments, methods may comprise forming the high-k dielectric material 136 to have a thickness of approximately less than 2 nanometers.

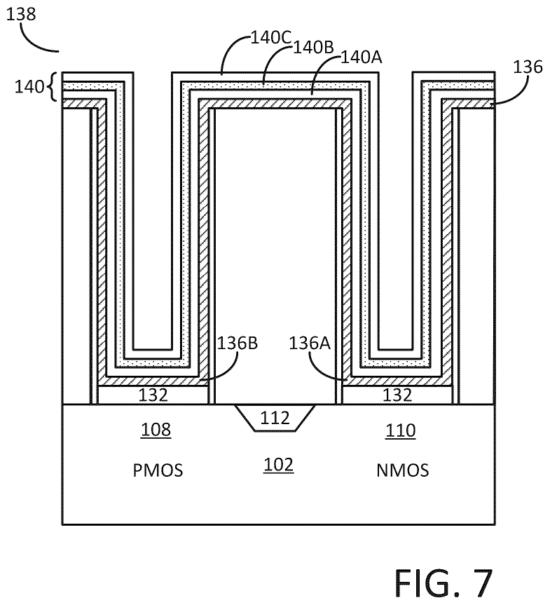

Embodiments of the disclosure may further comprise depositing a first work function metal over the NMOS gate dielectric and over the PMOS gate dielectric. In more detail and with reference to FIG. 7, a portion of an NMOS gate electrode 140 may be deposited over both the NMOS gate dielectric and over the PMOS gate dielectric. In some embodiments of the disclosure, the portion of the NMOS gate electrode 140 may comprise a first liner layer 140A, a first work function metal 140B and a second liner layer 140C. In some embodiments, the first liner layer 140A and the second liner layer 140C may comprise a metal nitride, such as a transition metal nitride, for example at least one of titanium nitride (TiN), tantalum nitride (TaN), or niobium nitride (NbN). In some embodiments of the disclosure, the first liner layer 140A and the second liner layer 140C may both comprise titanium nitride, i.e., a first titanium nitride film and a second titanium nitride film respectively. In some embodiments of the disclosure, the first liner layer 140A and the second liner layer 140C both comprise a doped titanium nitride (TiN), wherein the titanium nitride film may be doped with at least one of carbon (C), silicon (Si), or boron (B).

In some embodiments of the disclosure, the first work function metal may comprise a metal carbide, such as transition metal carbide, for example at least one of titanium carbide (TiCₓ), tantalum carbide (TaC), titanium aluminum carbide (TiAlCₓ) or niobium aluminum carbide or mixtures/laminates thereof. In some embodiments of the disclosure, the first work function metal may comprise a transition metal, such as Ti, Ta, or Nb and another metal such as Al and carbon. In some embodiments of the disclosure, the portion of the NMOS gate electrode 140 may be deposited by a cyclical deposition method, such as, for example, an atomic layer deposition process or cyclic CVD process.

In more detail, an ALD process is based on typically self-limiting reactions, whereby sequential and alternating pulses of reactants are used to deposit about one atomic (or molecular) monolayer of material per deposition cycle. The deposition conditions and precursors are typically selected to provide self-saturating reactions, such that an absorbed layer of one reactant leaves a surface termination that is non-reactive with the gas phase reactants of the same reactant. The substrate is subsequently contacted with a different reactant that reacts with the previous termination to enable continued deposition. Thus, each cycle of alternated pulses typically leaves no more than about monolayer of the desired material. However, as mentioned above, the skilled artisan will recognize that in one or more ALD cycles, more than one monolayer of material may be deposited, for example, if some gas phase reactions occur despite the alternating nature of the process.

In an ALD-type process for depositing a portion of NMOS gate electrode 140 comprising metal nitrides and metal carbides, one deposition cycle comprises exposing the substrate to a first reactant, removing any unreacted first reactant and reaction byproducts from the reaction space, exposing the substrate to a second reactant, followed by a second removal step. The first vapor phase reactant may comprise a metal precursor, such as a titanium precursor, a tantalum precursor, or a niobium precursor. The second precursor may comprise nitrogen precursor, an aluminum precursor, or a carbon precursor. In some embodiment, the second precursor may comprise both an aluminum precursor and a carbon precursor.

As a non-limiting example embodiment of the disclosure, the first liner layer 140A may comprise a first titanium nitride film (TiN) and may be deposited by an atomic layer deposition process directly over the surface of the high-k dielectric material 136. For example, atomic layer deposition of titanium nitride may comprise a first “metal phase” of a deposition cycle, which comprises contacting the substrate with a first vapor phase reactant which may include a titanium halide, such that the adsorbed monolayer is terminated with halogen ligands. In some embodiments, the titanium halide may comprise titanium tetrachloride (TiCl₄). In some embodiments of the disclosure, the titanium halide (e.g., titanium tetrachloride) may be pulsed into the reaction space over a time period of less than 20 seconds, or less than 10 seconds, or even less than 5 second.

Excess metal precursor (e.g., titanium precursor) and reaction byproducts (if any) may be removed from the substrate surface, e.g., by purging with an inert gas. Excess metal precursor and any reaction byproducts may be removed with the aid of a vacuum generated by a pumping system.

In a second phase of the deposition cycle (“the nitrogen phase”), the substrate is contacted with a nitrogen containing precursor, such as ammonia (NH₃) or hydrazine (N₂H₂). In some embodiments of the disclosure, the nitrogen containing precursor may comprise an alkyl-hydrazine precursor including, but not limited to, tertbutylhydrazine (C₄H₉N₂H₃), methylhydrazine (CH₃NHNH₂), dimethylhydrazine ((CH₃)₂N₂H₂). In some embodiments of the disclosure, the nitrogen containing precursor may comprise nitrogen radicals, atoms, or plasma. In some embodiments of the disclosure, the nitrogen precursor (e.g., ammonia) may be pulsed into the reaction space for a time period of less than 20 seconds, or less than 10 seconds, or even less than 5 seconds. The nitrogen reactant may react with the titanium-containing molecules left on the substrate surface. Preferably, in the second phase, nitrogen is incorporated in to the film by the interaction of the nitrogen reactant with the monolayer left by the metal precursor. In some embodiments, the reaction between the nitrogen reactant and the chemisorbed metal species produces a titanium nitride thin film over the substrate.

Excess second source chemical and reaction byproduct, if any, are removed from the substrate surface, for example by a purging gas pulse and/or vacuum generated by a pumping system. Purging gas is preferably any inert as, such as, without limitation, argon (Ar), nitrogen, (N₂), or helium (He). A phase is generally considered to immediately follow another phase if a purge (i.e., a purging pulse) or other reactant removal step intervenes.

The deposition cycle comprising contacting the substrate with the titanium precursor, purging the reaction space, contacting the substrate with the nitrogen precursor and purging the reaction space may be repeated two or more times until the desired thickness of the first liner layer 140A (e.g., the first titanium nitride film) is achieved. In some embodiments of the disclosure, the first liner layer 140A comprises titanium nitride (TiN) and is deposited to a thickness of less than 5 Angstroms, or less than 15 Angstroms, or even less than 30 Angstroms nanometers.

In some embodiments of the disclosure, the substrate may be heated to a desired deposition temperature during the atomic layer deposition processes, therefore the ALD process for the deposition of the first liner layer 140A may be performed at a substrate temperature of less than approximately 550° C., or less than approximately 350° C., or even less than approximately 150° C. In additional embodiments of the disclosure, the reaction space in which the atomic layer deposition of the first liner layer 140A takes place may be placed under a vacuum utilizing a pumping system fluidly connected to the reaction space. Therefore in some embodiments of the disclosure, the ALD process for depositing the first liner layer may take place at reaction space pressure of less than 10 Torr, or even less than 5 Torr, or even less than 1 Torr.

The process of depositing the portion of the NMOS gate electrode 140 may proceed by the atomic layer deposition of a first work function metal 140B directly over the surface of the first liner layer 140A, e.g., directly over the first titanium nitride film. In some embodiments of the disclosure, the first work function metal may comprise at least one of titanium carbide (TiC), tantalum carbide, titanium aluminum carbide (TiAlC), or niobium aluminum carbide (NbAlC).

The atomic layer deposition of the first work function metal 140B may comprise a deposition cycle including contacting the substrate with a first vapor phase reactant comprising a metal precursor, purging the reaction space, contacting the substrate with a second vapor phase reactant comprising a carbon precursor and in some embodiments an additional metal precursor, and purging the reaction space.

In some embodiments of the disclosure, the deposition of the first work function metal may comprise a deposition cycle which includes a first “metal phase” wherein the first metal phase comprises contacting the substrate with a titanium containing precursor, a tantalum containing precursor, or a niobium containing precursor. In some embodiments of the disclosure, the first metal phase of the ALD process comprises contacting the substrate with a titanium halide, such as, for example, titanium tetrachloride (TiCl₄). In some embodiments of the disclosure, the first metal phase of the ALD process comprises contacting the substrate with a tantalum halide, such as, for example, tantalum pentachloride (TaCl₅). In some embodiments of the disclosure, the first metal phase of the ALD process comprises contacting the substrate with a niobium halide, such as, for example, niobium pentachloride (NbCl₅) or niobium pentafluoride (NbF₅). For example, if the first work function metal comprises titanium carbide or titanium aluminum carbide then the first metal phase of the ALD deposition cycle may comprise contacting the substrate with titanium tetrachloride (TiCl₄), whereas if the first work function metal comprises niobium aluminum carbide, then the first metal phase of the ALD deposition cycle may comprise contacting the substrate with niobium pentachloride (NbCl₅). In some embodiments of the disclosure, the substrate may be contacted with the first metal precursor (e.g., titanium tetrachloride) for a time period of less than 20 seconds, or less than 10 seconds, or even less than 1 second.

Excess metal precursor (e.g., titanium precursor) and reaction byproducts (if any) may be removed from the substrate surface, e.g., by purging with an inert gas. Excess metal precursor and any reaction byproducts may be removed with the aid of a vacuum generated by a pumping system.

In a second phase of the deposition cycle utilized to deposit the first work function metal 140B, the substrate may be contact with a second vapor phase reactant comprising at least one of carbon and an additional metal containing precursor. In some embodiments of the disclosure, the first work function metal 140B may comprise titanium carbide and the second vapor phase reactant may comprise a carbon containing precursor, including, but not limited to, boron source compounds, silicon source compounds, phosphorus source compounds, or hydrocarbons. In more detail, the boron source compounds may comprise boron compounds that have at least one boron-carbon bond and may be chosen from the following:
Carboranes having the formula C₂BₙHₙ₊ₓ, wherein n is an integer from 1 to 10, and x is an even integer, preferably 2, 4 or 6. Examples of carboranes may include closo-carboranes (C₂BₙHₙ₊₂), nido-carboranes (C₂BₙHₙ₊₄), and arachno-carboranes (C₂BₙHₙ₊₆).
Amine-borane adducts having the formula R₃NBX₃, wherein R is linear or branched C1 to C10, preferably C1 to C4 alkyl or H, and X is linear or branched C1 to C10, preferably C1 to C4 alkyl, H or halogen.
Aminoboranes, where one or more of the substituents on the B is an amino group according to the formula R₂N, wherein R is linear or branched C1 to C10, preferably C1 to C4 alkyl or substituted or unsubstituted aryl group. An example of a suitable aminoborane is (CH₃)₂NB(CH₃)₂.
Alkyl borons or alkyl boranes, wherein the alkyl is typically linear or branched C1 to C10 alkyl, preferably C2 to C4 alkyl. For example, the alkyl boron may comprise triethylboron (CH₃CH₂)₃B.

In some embodiments of the disclosure, the carbon containing precursor may comprise an alkyl silicon compound, or an alkyl phosphorous compound. In some embodiments, the carbon containing precursor may comprise a hydrocarbon, such as, for example, a hydrocarbon with a high hydrogen/carbon ratio. In some embodiments, the carbon containing precursor may comprise a metalorganic compound, such as, for example trimethylaluminum (TMA). Atomic layer deposition of transition metal carbides are described in U.S. Pat. No. 6,800,552 issued to Elers et al., and incorporated by reference herein.

In some embodiments of the disclosure, the first work function metal 140B may comprise titanium aluminum carbide or niobium aluminum carbide and the second vapor phase reactant may comprise a carbon and aluminum containing precursor, including, but not limited to, aluminum hydrocarbon compounds selected from one or more of the group consisting of trimethylaluminum (TMA), triethylaluminum (TEA), dimethylaluminum hydride (DMAH), dimethylethylaminealane (DMEAA), trimethylaminealane (TEAA), N-methylpyrroridinealane (MPA), tri-isobutylaluminum (TIBA), and tritertbutylaluminum (TTBA). In some embodiments, the aluminum hydrocarbon compound comprises a tertbutyl ligand bonded to aluminum. In some embodiments, the aluminum hydrocarbon compound comprises at least one or more Al—C bonds. In some embodiments, the aluminum hydrocarbon compound comprises two or less Al—H bonds. In some embodiments, the aluminum hydrocarbon does not comprise Al—Al bonds. In some embodiments, the aluminum hydrocarbon compound does not comprise oxygen and/or a halide. In some embodiments, the aluminum hydrocarbon compound comprises only aluminum, hydrogen and carbon and no other elements. In some embodiments of the disclosure, the substrate may be contacted with the second vapor phase reactant (e.g., trimethylaluminum) for a time period of less than 20 seconds, or less than 10 seconds, or even less than 1 seconds.

The deposition cycle for depositing the first work function metal 140B comprising, contacting the substrate with a first metal containing precursors, purging the reaction space, contacting the substrate with a second vapor phase reactant which comprises at least one of carbon and an additional metal, and purging the reaction space, may be repeated two or more times until the desired thickness of the first work function metal is deposited. In some embodiments of the disclosure, the first work function metal 140B is deposited to thickness of less than 5 nanometers, or less than 4 nanometers, or even less than 3 nanometers.

In some embodiments of the disclosure, the substrate may be heated to a desired deposition temperature during the atomic layer deposition processes for the first work function metal 140B, therefore the ALD process for the deposition of the first work function metal 104B may be performed at a substrate temperature of less than approximately 550° C., or less than approximately 400° C., or even less than approximately 300° C. In additional embodiments of the disclosure, the reaction space in which the atomic layer deposition of the first work function metal 140B takes place may be placed under a vacuum utilizing a pumping system fluidly connected to the reaction space. Therefore in some embodiments of the disclosure, the ALD process for depositing the first work function metal layer may take place at reaction space pressure of less than 10 Torr, or even less than 5 Torr, or even less than 1 Torr.

Excess second vapor phase reactant (e.g., TMA) and reaction byproducts (if any) may be removed from the substrate surface, e.g., by purging with an inert gas. Excess second vapor phase reactant and any reaction byproducts may be removed with the aid of a vacuum generated by a pumping system.

The deposition of a portion of the NMOS gate electrode 140 may proceed with the deposition of the second liner layer 140C. In some embodiments of the disclosure, the second liner layer 140C may be deposited directly over the surface of the first work function metal 140B. In some embodiments of the disclosure, the second liner layer 140C may comprise at least one of titanium nitride, tantalum nitride, or niobium nitride. In some embodiments, the second liner layer 140C may comprise titanium nitride, i.e., a second titanium nitride film, and may be deposited by the same or substantially similar atomic layer deposition process as described herein for the first liner layer 140A. In some embodiments of the disclosure, the second liner layer 140C comprises titanium nitride (TiN) and is deposited to a thickness of less than 4 nanometers, or less than 3 nanometers, or even less than 2 nanometers.

In some embodiments of the disclosure, the portion of the NMOS gate electrode 140 formed over the semiconductor substrate by a cyclical deposition process, such as, for example, atomic layer deposition, may be deposited over a three dimensional structure, as illustrated in FIG. 7 wherein the portion of the NMOS gate electrode 140 is deposited over and in the gate trenches of semiconductor device structure 138. Therefore in some embodiments, the step coverage of a portion of NMOS gate electrode 140 may be equal to or greater than about 50%, or greater than about 80%, or greater than about 90%, or greater than about 95%, or greater than about 98%, or greater than about 99%, or even about 100% in structures having aspect ratios (height/width) of more than about 2, more than 5, more than about 10, more than about 25, more than about 50, or even more than about 100.

In some embodiments the growth rate of the portion of the NMOS gate electrode 140 may be less than about 5 Å/cycle, or less than about 2 Å/cycle, or even less than about 1 Å/cycle.

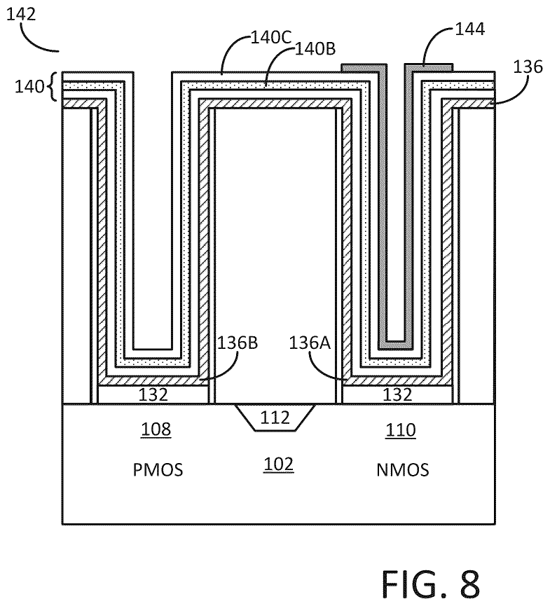

The embodiments of the disclosure may continue with the formation of a masking layer over select portions of the first work function metal, wherein the masking layer defines the areas of the first work function metal to remain after a subsequent removal process. For example, FIG. 8 illustrates semiconductor device structure 142 which comprises a masking layer 144 which may be disposed over select portions of the first work function metal 140B. The masking layer 144 may be formed and patterned using common semiconductor processes such as spin-coating, deposition, photolithography, development and etching. In some embodiments, the methods of the disclosure may comprise selecting the masking layer 144 to comprise at least one of a silicon oxide, a silicon nitride, a silicon oxynitride, or a polymer material (e.g., a photoresist). The masking layer 144 may be disposed over the portions of the first work function metal 140B that may remain after a subsequent removal process, i.e., the masking layer may be disposed over the NMOS gate dielectric 136A.

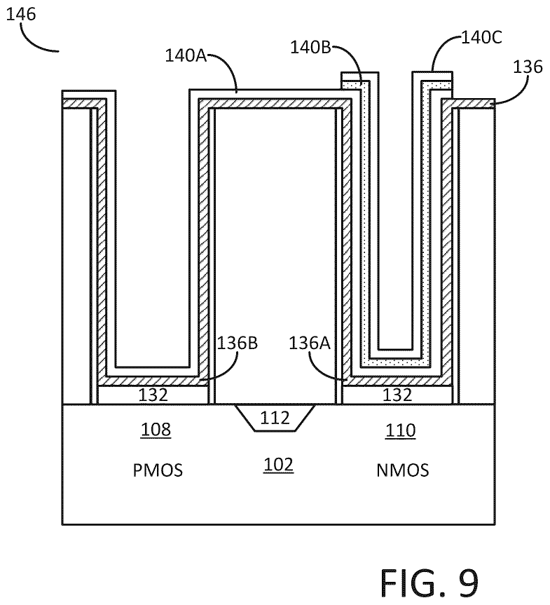

Embodiments of the disclosure may further comprise, removing the first work function metal over the PMOS gate dielectric. In more detail, FIG. 9 illustrates the semiconductor device structure 146 which comprises the first work function metal after removing a portion of the first work function metal 140, in addition to removing the masking layer. Removing the first work function metal over the PMOS gate dielectric may comprise selectively etching the second liner layer 140C, e.g., a second titanium nitride film, disposed over the PMOS gate dielectric 136B and selectively etching the first work function metal 140B disposed over the PMOS gate dielectric 136B. The term “selectively etching” may refer to an etching process in which a first material is etched at a significantly higher etching rate than a second material. For example, a ratio of the etching rates between the first material, e.g., the first work function metal, and the second material, e.g., the underlying first liner layer 140A, may comprise an etching ratio greater than 3:1, 5:1, or even 10:1 or even greater. In some embodiments of the disclosure, it may be difficult to obtain an selective etch process which is selective to the first work function metal 140B relative to the underlying first liner layer 140C. Therefore, in some embodiments of the disclosure, removing the first work function metal 140B over the PMOS dielectric 136B further comprises removing at least a portion of the first liner layer 140A, e.g., a first titanium nitride film. In some embodiments, removing the first work function metal 140B over the PMOS dielectric 136B may comprise completely removing the region of the first liner layer 140A disposed over the PMOS dielectric 136B.

In some embodiments of the disclosure, selectively etching the first work function metal 140B further comprises, exposing the first work function metal 140B to at least one of a fluoride-based etch chemistry or a chloride-based etch chemistry. As a non-limiting example, the selective etch process may comprise exposing both the second liner layer 140C, e.g., the second titanium nitride film, and the first work function metal 140B to at least one of sulfur hexafluoride (SF₆), carbon tetrafluoride (CF₄), or nitrogen trifluoride (NF₃). In further embodiments of the disclosure, the etching of the second liner layer 140C and the first work function metal 140B may comprise one or more of a polishing, grinding or chemical mechanical polishing removal process. As illustrated in FIG. 9 the removal process results in a first work function metal 140B disposed over the NMOS gate dielectric 136A.

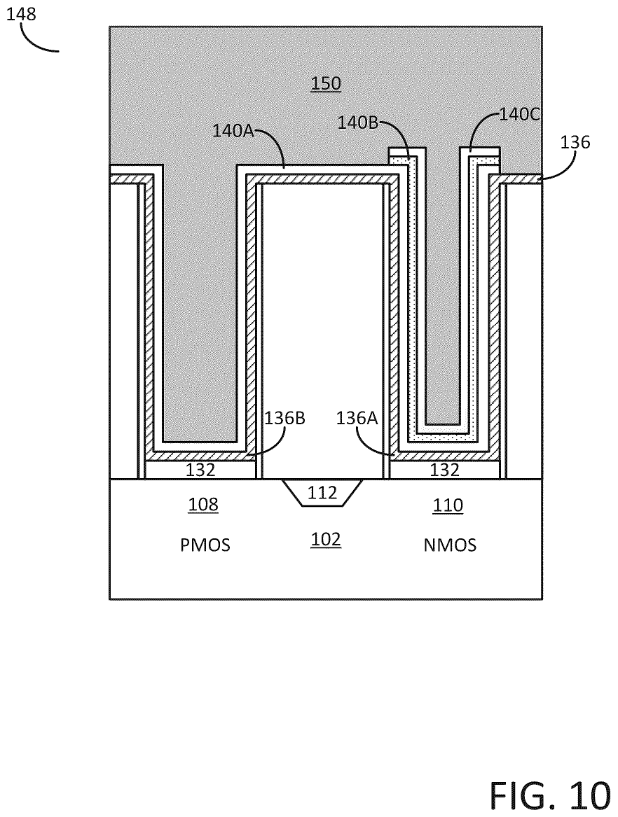

Embodiments of the disclosure may further comprise, depositing a second work function metal over the NMOS gate dielectric and over the PMOS gate dielectric. As illustrated in FIG. 10, semiconductor device structure 148 may include a second work function metal 150 that may be formed conformally over the NMOS gate dielectric 136A and over the PMOS gate dielectric 136B. In some embodiments, the second work function metal 150 may be disposed directly over the first liner layer 140A, e.g., a first titanium nitride film, in the region disposed over the PMOS gate dielectric 136B. In some embodiments, the second work function metal 150 may be disposed directly over the second liner layer 140C and over the first work function metal 104B in the region disposed over the NMOS gate dielectric 136A. As illustrated in FIG. 10, the second work function metal 150 not only comprises a second work function metal but also fills the gate trench structure such that the remaining portions of the gate trench are completed filled with the second work function metal 150, therefore the second work function metal comprises a gate fill metal.

In some embodiments of the disclosure, the second work function metal 150 may comprise a molybdenum film and the molybdenum film may be deposited utilizing a cyclical deposition process, such as, for example, an atomic layer deposition process. Therefore, the method of depositing the second work function metal 150 may comprise alternatively and sequentially contacting the semiconductor substrate with a molybdenum precursor and a reducing agent precursor. For example, in some embodiments of the disclosure, depositing the second work function metal 150 may comprise depositing a molybdenum film by atomic layer deposition, the ALD process comprising a deposition cycle which includes, contacting the semiconductor substrate with a first vapor phase reactant comprising a molybdenum containing precursor, purging the reaction space, contacting the semiconductor structure with a second vapor phase reactant comprising a reducing agent precursor and purging the reaction space for a second time.

In some embodiments of the disclosure, a deposition cycle for depositing a second work function metal 150 (e.g., a molybdenum film) includes a first metal phase which comprises contacting substrate with a first vapor phase reactant comprising a molybdenum containing precursor. In some embodiments, the molybdenum precursor may comprise molybdenum and a halogen, such as, for example, a chloride. In some embodiments, the molybdenum precursor may comprise molybdenum, a halogen and a chalcogenide, wherein the chalcogenide may comprise oxygen. In some embodiments, the molybdenum precursor may comprise at least one of molybdenum pentachloride (MoCl₅) or molybdenum dichloride dioxide (MoO₂Cl₂). In some embodiments, the molybdenum containing precursor may be pulsed into the reaction space for a time period of less than 20 second, or less than 10 second, or even less than 1 second.

Excess first vapor phase reactant (e.g., molybdenum pentachloride) and reaction byproducts (if any) may be removed from the substrate surface, e.g., by purging with an inert gas. Excess second vapor phase reactant and any reaction byproducts may be removed with the aid of a vacuum generated by a pumping system.

The second phase of the deposition cycle for depositing a molybdenum film may comprise a reducing phase, in which the substrate is exposed to one or more reducing agent precursors which react with the molybdenum ligands present on the semiconductor substrate thereby forming a molybdenum film. Therefore, in some embodiments of the disclosure, the second phase of the cyclical deposition cycle comprises contacting the semiconductor substrate with a reducing agent precursor, the reducing agent precursor comprising at least one of hydrogen (H₂), silane (SiH₄), disilane (Si₂H₆), trisilane (Si₃H₈), germane (GeH₄), digermane (Ge₂H₆), or diborane (B₂H₆). In some embodiments of the disclosure, the reducing agent precursor may comprise hydrogen (H₂) or hydrogen radicals, atoms, or plasma, i.e., excited species of hydrogen created utilizing a hydrogen plasma, e.g., either a remote or direct plasma. In some embodiments, the reducing agent precursor may comprise higher order silanes with the general empirical formula SiₓH₍₂ₓ₊₂₎. In some embodiments, the reducing agent precursor may comprise higher order germanes with the general empirical formula GeₓH₍₂ₓ₊₂₎. In some embodiments, the reducing agent precursor may be pulsed into the reaction space for time period of less than 20 seconds, or less than 10, or even less than 1 second.

In some embodiments of the disclosure, the second work function metal 150 may be deposited to a thickness such that the gate trench is completely filled with the second work function metal, i.e., the second work function metal is utilized as a gate fill metal. For example, in some embodiments of the disclosure the second work function metal 150 may comprise a molybdenum film deposited to a thickness of between approximately 50 nanometers and 300 nanometers or between approximately 5 nanometers and 50 nanometers.

In some embodiments of the disclosure, the substrate may be heated to a desired deposition temperature during the atomic layer deposition processes for the second work function metal 150, therefore the ALD process for the deposition of the second work function metal 150 may be performed at a substrate temperature of less than approximately 750° C., or less than approximately 650° C., or less than approximately 550° C., or less than approximately 450° C., or less than approximately 350° C., or less than approximately 250° C., or even less than approximately 150° C. In some embodiments of the disclosure, the deposition of the second work function metal may be performed at a substrate temperature of between 300° C. and 750° C., or between 400° C. and 700° C., or between 450° C. and 600° C.

In additional embodiments of the disclosure, the reaction space in which the atomic layer deposition of the second work function metal 150 takes place may be placed under a vacuum utilizing a pumping system fluidly connected to the reaction space. Therefore in some embodiments of the disclosure, the ALD process for depositing the second work function metal layer may take place at reaction space pressure of less than 10 Torr, or even less than 5 Torr, or even less than 1 Torr.

In some embodiments of the disclosure, the second work function metal 150 formed over the semiconductor substrate by a cyclical deposition process, such as, for example, atomic layer deposition, may be deposited over a three dimensional structure, as illustrated in FIG. 10 wherein the second work function metal completely fills the gate trench and therefore comprises a gate fill metal. Therefore in some embodiments, the step coverage of the second work function metal 150 may be equal to or greater than about 50%, or greater than about 80%, or greater than about 90%, or greater than about 95%, or greater than about 98%, or greater than about 99%, or even about 100% in structures having aspect ratios (height/width) of more than about 2, more than 5, more than about 10, more than about 25, more than about 50, or even more than about 100. In additional embodiments the Mo film may comprise less than about 20 atomic % oxygen, less than about 10 atomic % oxygen, less than about 5 atomic % oxygen, or even less than about 2 atomic % oxygen. In further embodiments, the Mo film may comprise less than about 10 atomic % hydrogen, or less than about 5 atomic % of hydrogen, or less than about 2 atomic % of hydrogen, or even less than about 1 atomic % of hydrogen. In some embodiments, the Mo film may comprise Halide/Cl less than about 10 atomic %, or Halide/Cl less than about 5 atomic %, Halide/C1 less than about 1 atomic %, or even Halide/C1 less than about 0.5 atomic %. In yet further embodiments, the Mo film may comprise less than about 10 atomic % carbon, or less than about 5 atomic % carbon, or less than about 2 atomic % carbon, or less than about 1 atomic % of carbon, or even less than about 0.5 atomic % carbon. In the embodiments outlined herein, the atomic concentration of an element may be determined utilizing Rutherford backscattering (RBS).

In some embodiments the growth rate of the second work function metal 150 may be less than about 5 Å/cycle, or less than about 2 Å/cycle, or even less than about 1 Å/cycle.

In some embodiments of the disclosure, prior to depositing the second work function metal 150, a third liner layer (not shown) may be deposited over the PMOS gate dielectric 136B and the NMOS gate dielectric 136A. In some embodiments, the third liner layer may comprise at least one of titanium nitride, tantalum nitride, or niobium nitride. In some embodiments, the third liner layer may comprise a third titanium nitride film deposited utilizing the atomic layer deposition processes described herein. The third titanium nitride film may be utilized in embodiments wherein the removal stage completely or partially removes the first liner layer 140A disposed above the PMOS dielectric 136B. Therefore, in some embodiments of the disclosure, the thickness of the first liner layer 140A may different between that disposed over the PMOS region 108 and the NMOS region 110.

In some embodiments of the disclosure, the semiconductor device structure 148 of FIG. 10 comprises a metal nitride film, such as, for example, titanium nitride disposed directly over the PMOS gate dielectric 136B. In some embodiments, the metal nitride film disposed directly over the PMOS gate dielectric 136B comprises either the first liner layer 140C, or a third liner layer, depending on whether the first liner layer 140C is completely removed during the removal process to remove the first work function metal 140C disposed over the PMOS dielectric 136B. In some embodiments of the disclosure, the thickness of the metal nitride film disposed directly over the PMOS gate dielectric 136B may be varied to enable the tuning of an effective work function of a metal gate electrode disposed over the PMOS gate dielectric. For example, in some embodiments of the disclosure, the metal nitride film disposed directly over the PMOS gate dielectric is varied in thickness between approximately 5 Angstroms and approximately 30 Angstroms. In some embodiments of the disclosure, the metal gate electrode disposed over the PMOS dielectric 136 comprises a metal nitride film 140A, such as, for example, titanium nitride directly in contact with the PMOS dielectric 136 and a further second effective work function metal, e.g., a molybdenum film, disposed directly over the metal nitride film 140A. As a non-limiting example embodiment of the disclosure, the gate electrode to the PMOS device comprises a titanium nitride film and a molybdenum film and the effective work function of the gate electrode to the PMOS device varies, i.e., is tuned to a preferred value, by varying the thickness of the titanium nitride film 140A in direct contact with the PMOS dielectric 136. For example, in some embodiments the thickness of the titanium nitride film disposed directly over the PMOS gate dielectric is varied in thickness between approximately 5 Angstroms and approximately 30 Angstroms, resulting in an effective work function of the PMOS gate electrode of between approximately 5.2 eV and approximately 4.8 eV.

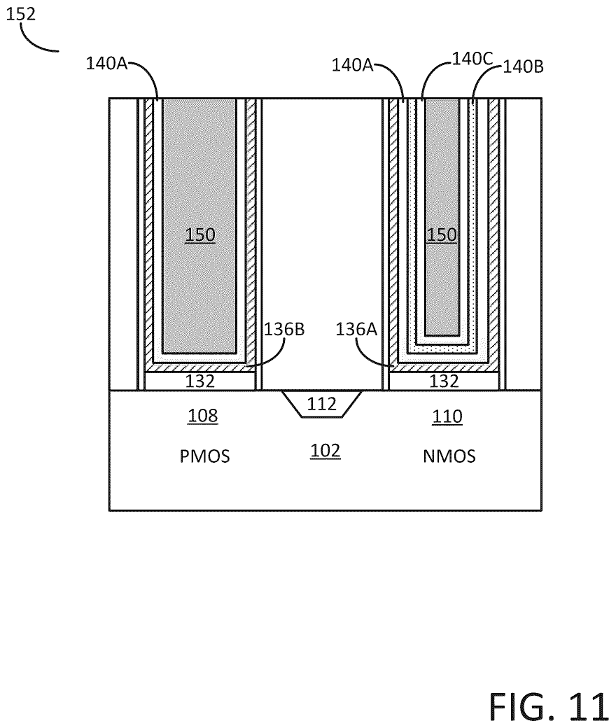

Subsequent processes in the embodiments of the disclosure may selectively remove excess material from the surface of semiconductor device structure 148 of FIG. 10. As illustrated by semiconductor device structure 152 of FIG. 11, wherein one or more etching and or polishing processes may be utilized to form the planarized semiconductor device structure 152. Upon formation of semiconductor device structure 152 of FIG. 11, further processes may be performed to complete the semiconductor device structure, e.g., to complete a complementary metal-oxide-semiconductor (CMOS) device structure. For example, back-end-of-line processes may form contacts to the gate electrode structures and to source/drain regions as well as forming interconnects between the devices on the semiconductor substrate 102.

Embodiments of the disclosure may also comprise semiconductor device structures formed accordingly to the methods of the disclosure. For example, FIG. 11 illustrates the semiconductor device structure 152 which comprises a PMOS gate electrode disposed over a PMOS gate dielectric, wherein the PMOS gate electrode comprises a metal nitride film 140A, such as, for example, titanium nitride disposed directly over the PMOS gate dielectric 136B and a molybdenum film 150 disposed directly over the metal nitride film 140A. In some embodiments of the disclosure, the PMOS gate electrode has an effective work function of greater than approximately 4.9 eV, or greater than approximately 5.0 eV, or even greater than approximately 5.1 eV. In some embodiments, the metal nitride film disposed directly over the PMOS gate dielectric has a thickness of less than 30 Angstroms. In some embodiments, the molybdenum film disposed directly over the metal nitride film has a thickness of less than 10 nanometers. In some embodiments, the PMOS gate dielectric 136B may comprise at least one of hafnium oxide (HfO₂), aluminum oxide (Al₂O₃), tantalum oxide (Ta₂O₅), zirconium oxide (ZrO₂), titanium oxide (TiO₂), hafnium silicate (HfSiOₓ) and lanthanum oxide (La₂O₃). In some embodiments, the molybdenum film functions as both a work function metal and a gate fill metal, the gate fill metal being disposed in and filling the gate trench. In some embodiments of the disclosure, the metal nitride film 140A disposed directly above the PMOS gate dielectric 136B may be varied in thickness to thereby vary the effective work function of the gate electrode. For example, the metal nitride film 140 A may comprise a titanium nitride film and may have a thickness between approximately 5 Angstroms and approximately 30 Angstroms, resulting in an effective work function for the metal gate stack of between approximately 5.2 eV and approximately 4.8 eV.

The semiconductor device structure 152 of FIG. 11 may also comprise a NMOS gate electrode disposed over a NMOS gate dielectric, wherein the NMOS gate electrode comprises a metal nitride film 140A disposed directly over the NMOS gate dielectric 136A, a first work function metal 140B disposed directly over the metal nitride film 140A, an additional metal nitride film 140C disposed over the first work function metal 140B and a molybdenum film 150 disposed directly over the additional metal nitride film 140B.

In some embodiment of the disclosure, the NMOS gate electrode has an effective work function of less than 4.5 eV, or less than 4.3 eV, or even less than 4.2 eV. In some embodiments of the disclosure, the NMOS gate electrode has an effective work function of 4.3 eV. In some embodiments, the metal nitride film disposed directly over the NMOS gate dielectric has a thickness of less than 4 nanometers. In some embodiments of the disclosure, the metal nitride film may comprise at least one of titanium nitride, tantalum nitride, or niobium nitride. In some embodiments, the first work function metal 140B comprises at least one of titanium carbide (TiC), tantalum carbide (TaC), titanium aluminum carbide (TiAlC), or niobium aluminum carbide (NbAlC), wherein the first work function metal 140B has a thickness of less than 4 nanometers. In some embodiments, the additional metal nitride film 140C disposed directly over the first work function metal, has a thickness of less than 3 nanometers. In some embodiments of the disclosure, the additional metal nitride film 140C may comprise at least one of titanium nitride, tantalum nitride, or niobium nitride. In some embodiments, the molybdenum film 150 disposed directly over the additional metal nitride film 140C has a thickness of less than 10 nanometers. In some embodiments, the molybdenum film comprises a gate fill metal, the gate fill metal being disposed in and filling the gate trench. In some embodiments of the disclosure, the molybdenum film 150 has an electrical resistivity of less than approximately 50 μΩcm, or less than approximately 30 μΩcm, or even less than approximately 20 μΩcm.

The embodiments of the disclosure may also comprise a complementary metal-oxide-semiconductor (CMOS) device structure, as illustrate in FIG. 11. The CMOS device structures may comprise a PMOS gate electrode disposed over a PMOS gate dielectric, wherein the PMOS gate electrode comprises a first titanium nitride film 140A disposed directly over the PMOS gate dielectric 136B and a molybdenum film 150 disposed directly over the first titanium nitride film 140A. The CMOS device structure may further comprise a NMOS gate electrode disposed over a NMOS gate dielectric, wherein the NMOS gate electrode comprises a second titanium nitride film 140A disposed directly over the NMOS gate dielectric 136A, a first work function metal 140B disposed directly over the second titanium nitride film 140A, a third titanium nitride film 140C disposed directly over the first work function metal and a molybdenum film 150 disposed directly over the third titanium nitride film 140C.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

1. A method for forming a semiconductor device structure comprising:
providing a substrate comprising a plurality of trenches, wherein the plurality of trenches comprise at least one NMOS gate trench and at least one PMOS gate trench;
depositing a gate dielectric over the plurality of trenches;
depositing a NMOS gate electrode over the plurality of trenches such that the NMOS gate electrode spans a surface of the gate dielectric in the plurality of trenches;
removing at least a portion of the NMOS gate electrode in the at least one PMOS gate trench; and
after removing at least a portion of the NMOS gate electrode in the at least one PMOS gate trench, depositing a first work function metal in the plurality of trenches.

2. The method of claim 1, wherein depositing a NMOS gate electrode comprises:
depositing a first liner layer;
depositing a second work function metal; and
depositing a second liner layer.

3. The method of claim 2, wherein the step of removing at least a portion of the NMOS gate electrode comprises removing the second liner layer and the second work function metal in the at least one PMOS gate trench.

4. The method of claim 2, wherein the step of removing at least a portion of the NMOS gate electrode comprises removing the second liner layer, the second work function metal, and at least a portion of the first liner layer in the at least one PMOS gate trench.

5. The method of claim 4, further comprising depositing a third liner layer after removing at least a portion of the first liner layer in the at least one PMOS gate trench and before depositing a second work function metal.

6. The method of claim 1, wherein depositing the dielectric material comprises a chemical vapor deposition (CVD), low pressure chemical vapor deposition (LPCVD), or plasma enhanced chemical vapor deposition (PECVD) process.

7. The method of claim 1, wherein depositing the first work function metal comprises a chemical vapor deposition (CVD) or atomic layer deposition (ALD) process.

8. The method of claim 1, wherein removing at least a portion of the NMOS gate electrode in the at least one PMOS gate trench comprises forming a masking layer in the at least one NMOS gate trench and exposing the substrate to an etchant.

9. The method of claim 8, wherein the etchant comprises at least one of sulfur hexafluoride (SF₆), carbon tetrafluoride (CF₄), or nitrogen trifluoride (NF₃).

10. The method of claim 1, wherein depositing the second work function metal comprises an atomic layer deposition, wherein the atomic layer deposition comprises alternately and sequentially contacting the semiconductor substrate with a molybdenum precursor and a reducing agent precursor.

11. The method of claim 10, wherein the molybdenum precursor comprises molybdenum and a halogen.

12. The method of claim 11, wherein the molybdenum precursor comprises at least one of molybdenum pentachloride (MoCl₅) or molybdenum dichloride dioxide (MoO₂Cl₂).

13. The method of claim 10, wherein the reducing agent precursor comprises hydrogen (H₂).

14. A method for forming a NMOS semiconductor device structure comprising:
providing a substrate comprising at least one trench;
depositing a gate dielectric over the at least one trench;
depositing a NMOS gate electrode such that the NMOS gate electrode spans a surface of the gate dielectric in the plurality of trenches; and
depositing a first work function metal in the at least one trench, wherein the first work function metal comprises molybdenum.

15. The method of claim 14, wherein depositing the second work function metal comprises an atomic layer deposition, wherein the atomic layer deposition comprises alternately and sequentially contacting the semiconductor substrate with a molybdenum precursor and a reducing agent precursor.

16. The method of claim 15, wherein the molybdenum precursor comprises at least one of molybdenum pentachloride (MoCl₅) or molybdenum dichloride dioxide (MoO₂Cl₂).

17. The method of claim 14, wherein depositing a NMOS gate electrode comprises:
depositing a first liner layer;
depositing a second work function metal; and
depositing a second liner layer.

18. A method for forming a PMOS semiconductor device structure comprising:
providing a substrate comprising at least one trench;
depositing a gate dielectric over the at least one trench;
depositing a first liner layer directly onto the gate dielectric such that the first liner layer spans a surface of the gate dielectric in the plurality of trenches; and
depositing a first work function metal onto the first liner layer, wherein the first work function metal comprises molybdenum.

19. The method of claim 18, wherein depositing the second work function metal comprises an atomic layer deposition, wherein the atomic layer deposition comprises alternately and sequentially contacting the semiconductor substrate with a molybdenum precursor and a reducing agent precursor.

20. The method of claim 19, wherein the molybdenum precursor comprises at least one of molybdenum pentachloride (MoCl₅) or molybdenum dichloride dioxide (MoO₂Cl₂).
